(19) United States
(12) Patent Application Publication
(10) Pub. No.: US 2019/0081179 A1
(43) Pub. Date: Mar. 14, 2019

(54) THIN FILM TRANSISTOR, METHOD FOR FABRICATING THE SAME, ARRAY SUBSTRATE, AND DISPLAY DEVICE

(71) Applicant: BOE Technology Group Co., Ltd., Beijing (CN)

(72) Inventors: Jianguo WANG, Beijing (CN); Haixu LI, Beijing (CN)

(21) Appl. No.: 16/123,299

(22) Filed: Sep. 6, 2018

(30) Foreign Application Priority Data
Sep. 11, 2017 (CN) 201710813421.X

(51) Int. Cl. H01L 29/786; H01L 21/02; H01L 29/66

(52) U.S. Cl. CPC H01L 29/78633; H01L 21/02565; H01L 21/02628; G02F 1/1368; H01L 21/02488; H01L 29/7869; H01L 29/66969

(57) ABSTRACT

The disclosure relates to the field of display technologies, and discloses a thin film transistor, a method for fabricating the same, an array substrate, and a display device, and the method for fabricating a thin film transistor includes: forming a light-shielding layer pattern and an active layer pattern on an underlying substrate in a patterning process, wherein the active layer pattern is located on the side of the light-shielding layer pattern away from the underlying substrate, and the material of the light-shielding layer pattern is resin; and forming a gate insulation layer, a gate pattern, an interlayer insulation layer, and source and drain electrodes on the active layer pattern.

### CROSS-REFERENCE TO RELATED APPLICATION

This application claims priority of Chinese Patent Application No. 201710813421.X, filed on Sep. 11, 2017, which is hereby incorporated by reference in its entirety.

### FIELD

The present disclosure relates to the field of display technologies, and particularly to a thin film transistor, a method for fabricating the same, an array substrate, and a display device.

### BACKGROUND

Structures of a Thin Film Transistor (TFT) generally include a top-gate structure and a bottom-gate structure. For an array substrate in a liquid crystal display including TFTs in the top-gate structure, a pattern of a light-shielding layer which is an optical protection layer of a semiconductor layer is formed below the semiconductor layer to thereby prevent light emitted by a backlight source from being incident onto the semiconductor layer, which would otherwise have resulted in such light-inducted carriers that may degrade an electrical characteristic of the semiconductor layer.

### SUMMARY

The embodiments of the disclosure provide the following technical solutions.

An embodiment of the disclosure provides a method for fabricating a thin film transistor, the method including:

forming a light-shielding layer pattern and an active layer pattern on an underlying substrate in a patterning process, wherein the active layer pattern is arranged on a side of the light-shielding layer pattern away from the underlying substrate, and a material of the light-shielding layer pattern is resin; and

forming a gate insulation layer, a gate pattern, an interlayer insulation layer, and source and drain electrodes on the active layer pattern.

Optionally, the light-shielding layer pattern and the active layer pattern are formed on the underlying substrate in one patterning process.

Optionally, the material of the light-shielding layer pattern is photosensitive resin, and the patterning process for forming the light-shielding layer pattern and the active layer pattern formed on the underlying substrate includes:

coating photosensitive resin material on the underlying substrate, and forming a light-shielding thin film in a soft-baking process;

forming an active layer precursor thin film on the light-shielding thin film; and

exposing and developing, and sintering and curing the light-shielding thin film and the active layer precursor thin film into the light-shielding layer pattern and the active layer pattern.

Optionally, the forming the active layer precursor thin film on the light-shielding thin film includes:

coating indium acetylacetonate solution on the surface of the light-shielding thin film to form a thin film of indium acetylacetonate; and

dissolving active components of hydrated gallium nitrate and zinc oxide in organic solvent to form solution, coating the solution on the thin film of indium acetylacetonate, and exposing the thin film into a zinc-gallium-indium oxide precursor thin film.

Optionally, the forming the gate insulation layer, the gate pattern, the interlayer insulation layer, and the source and drain electrodes on the active layer pattern includes:

forming a gate metal layer on the gate insulation layer, etching the gate metal layer in a photolithography process to form the gate pattern, and conductizing a part of the active layer pattern, which is not covered with the gate pattern, into conductor areas by plasma etching;

forming the interlayer insulation layer on the gate pattern, and forming a through-hole on the interlayer insulation layer; and

forming a metal layer for source and drain electrodes on the interlayer insulation layer, and patterning the metal layer for source and drain electrodes into a source and drain electrodes pattern electrically connected with the active layer pattern through the through-hole.

An embodiment of the disclosure further provides a thin film transistor including:

a light-shielding layer pattern, and an active layer pattern, which are arranged on an underlying substrate, wherein the active layer pattern is arranged on a side of the light-shielding layer pattern away from the underlying substrate, and a material of the light-shielding layer pattern is resin.

Optionally, the thin film transistor further includes a gate insulation layer, a gate pattern, an interlayer insulation layer, and source and drain electrodes, arranged on the side of the active layer pattern away from the underlying substrate, wherein the thin film transistor further includes at least one of following features:

the material of the active layer is zinc-gallium-indium oxide or zinc-tin-indium oxide,

the material of the interlayer insulation layer is tin nitride, and the thickness of the interlayer insulation layer ranges from 300 nm to 400 nm, or

the material of the source and drain electrodes is metal molybdenum, metal aluminum, or metal copper, and the thickness of the source and drain electrodes ranges from 200 nm to 300 nm.

Optionally, the gate insulation layer is formed on a side of the active layer pattern away from the underlying substrate;

the gate pattern is formed on a side of the gate insulation layer away from the underlying substrate;

the interlayer insulation layer is formed on the a side of the gate pattern away from the underlying substrate; and

the source and drain electrodes are formed on a side of the interlayer insulation layer away from the underlying substrate, where the source and drain electrodes are connected with the active layer pattern through a through-hole.

Optionally, the source and drain electrodes are lapped on a side of the active layer pattern away from the underlying substrate;

the gate insulation layer is formed on a sides of the source and drain electrodes away from the underlying substrate;

the gate pattern is formed on a side of the gate insulation layer away from the underlying substrate; and

the interlayer insulation layer is formed on a side of the gate pattern away from the underlying substrate.

Optionally, the source and drain electrodes are arranged between the active layer pattern and the light-shielding layer pattern;

the gate insulation layer is formed on a side of the active layer pattern away from the underlying substrate;

the gate pattern is formed on a side of the gate insulation layer away from the underlying substrate; and

the interlayer insulation layer is formed on a side of the gate pattern away from the underlying substrate.

An embodiment of the disclosure further provides an array substrate including the thin film transistors according to any one of the technical solutions above.

An embodiment of the disclosure further provides a display device including the array substrate according to any one of the technical solutions above.

### BRIEF DESCRIPTION OF THE DRAWINGS

FIG. 1 is a schematic flow chart of a method for fabricating a thin film transistor according to some embodiments of the disclosure.

FIG. 2A to FIG. 2D are schematic diagrams of respective layers evolving while a thin film transistor is being fabricated in the method for fabricating a thin film transistor according to some embodiments of the disclosure.

FIG. 3 is a schematic structural diagram of a thin film transistor according to some embodiments of the disclosure.

FIG. 4 is a schematic structural diagram of a thin film transistor according to some embodiments of the disclosure.

### DETAILED DESCRIPTION OF THE EMBODIMENTS

In the related art, the light-shielding layer is deposited directly on the substrate to thereby prevent the light emitted by the backlight source from being incident onto the semiconductor layer, so an additional patterning process is performed, thus increasing a cost.

The technical solutions according to the embodiments of the disclosure will be described below clearly and fully with reference to the drawings in the embodiments of the disclosure, and apparently the embodiments described below are only a part but not all of the embodiments of the disclosure. Based upon the embodiments here of the disclosure, all the other embodiments which can occur to those skilled in the art without any inventive effort shall fall into the scope of the disclosure.

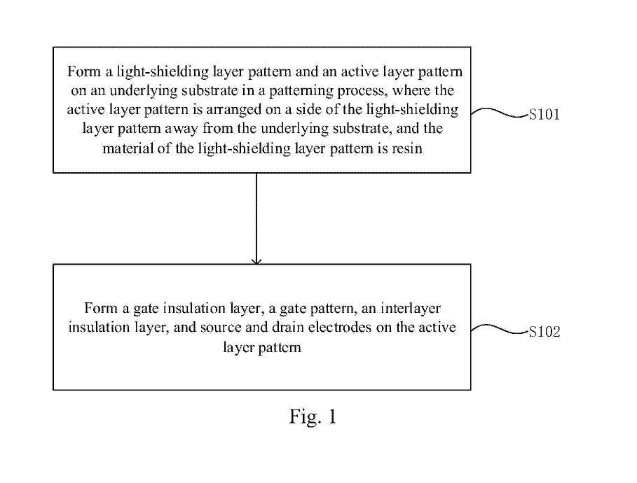

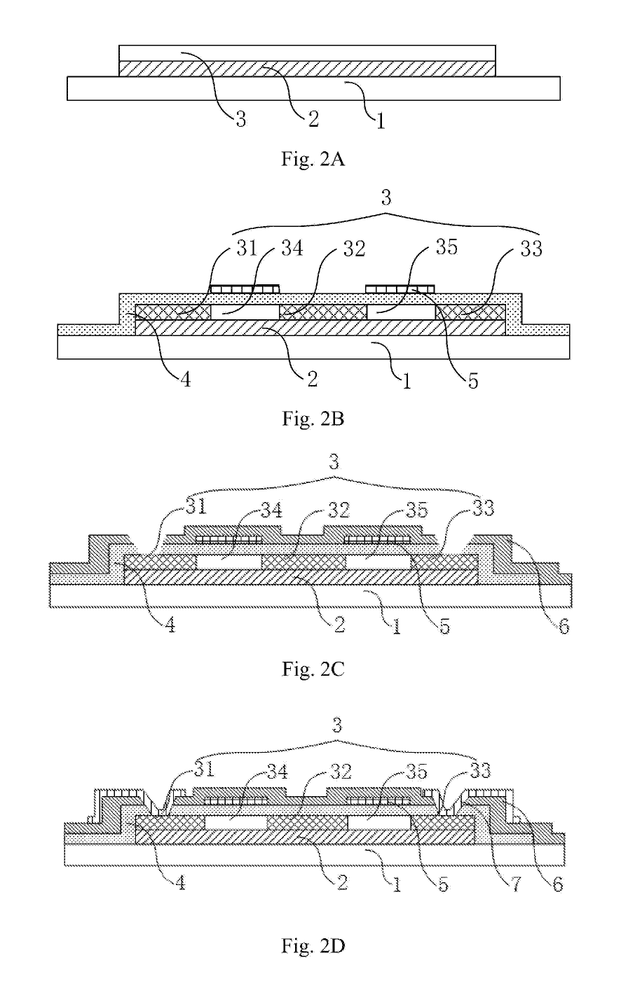

Referring to FIG. 1, and FIG. 2A to FIG. 2D, an embodiment of the disclosure provides a method for fabricating a thin film transistor, where the method includes the following steps.

Referring to FIG. 2A, the step S101 is to form a light-shielding layer pattern 2 and an active layer pattern 3 on an underlying substrate 1 in a patterning process, where the active layer pattern 3 is located on the side of the light-shielding layer pattern 2 away from the underlying substrate 1, and the material of the light-shielding layer pattern 2 is resin.

Referring to FIG. 2B to FIG. 2D, the step S102 is to form a gate insulation layer 4, a gate pattern 5, an interlayer insulation layer 6, and source and drain electrodes 7 on the active layer pattern 3.

In the method above for fabricating a thin film transistor, a light-shielding layer pattern 2 and an active layer pattern 3 are formed on an underlying substrate 1 in a patterning process, and a gate insulation layer 4, a gate pattern 5, an interlayer insulation layer 6, and source and drain electrodes 7 are formed on the active layer pattern 3. Since the active layer pattern 3 is located on the side of the light-shielding layer pattern 2 away from the underlying substrate 1, and the material of the light-shielding layer pattern 2 is resin, that is, the material of the light-shielding layer pattern 2 is not metal or another conductor, neither spraying, exposure and development, etching, and other processes will be performed, nor a buffer layer will be arranged between the light-shielding layer pattern 2 and the active layer pattern 3 to space them from each other, and the capacitance, which may degrade the stability and bias trustworthiness of the TFT, etc., can be avoided from being formed between the light-shielding layer pattern 2, and the source and drain electrodes 7. In this way, the number of process steps can be reduced, a cost can be saved, and a capacitance, and the number of inductive charges between the light-shielding layer pattern 2, and the source and drain electrodes 7 can be lowered, thus improving the stability and bias trustworthiness of the thin film transistors in an array substrate fabricated using this method.

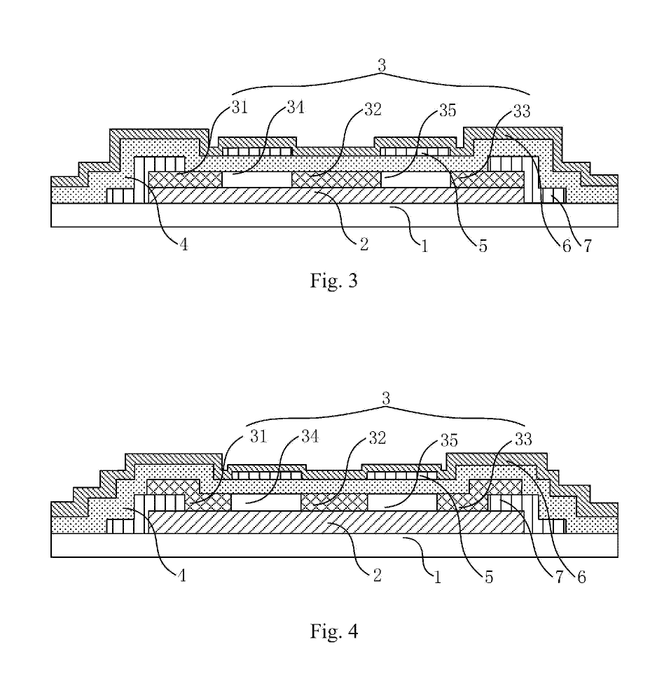

As can be appreciated that, as illustrated in FIG. 3 and FIG. 4, the gate pattern 5 can include two areas, so that the mobility of carriers will be high while the thin film transistor fabricated in this structure is operating; or of course, the gate pattern 5 can alternatively include only one area.

Accordingly in the method above for fabricating a thin film transistor, the process thereof is improved, and the number of steps in the process is reduced, thus improving the stability and bias trustworthiness of the thin film transistors in an array substrate fabricated using this method.

Further to the technical solution above, optionally, the light-shielding layer pattern 2 and the active layer pattern 3 are formed on the underlying substrate 1 in one patterning process.

Optionally, the material of the light-shielding layer pattern 2 is photosensitive resin, and the light-shielding layer pattern 2 and the active layer pattern 3 are formed on the underlying substrate 1 in the following patterning process.

Photosensitive resin material is coated on the underlying substrate 1, and forming a light-shielding thin film in a soft-baking process.

An active layer precursor thin film is formed on the light-shielding thin film.

The light-shielding thin film and the active layer precursor thin film are exposed and developed, and sintered and cured into the light-shielding layer pattern 2 and the active layer pattern 3.

It shall be noted that the material of the light-shielding thin film is photosensitive resin, so in the patterning process for forming the light-shielding layer pattern 2 and the active layer pattern 3 on the underlying substrate 1, a photosensitive component in a part of the light-shielding thin film being exposed undergoes a photochemical action, and is decomposed, so the part of the light-shielding thin film, and the active layer precursor thin film thereon are dissolved in development solution; and the other part of the light-shielding thin film, including the photosensitive component which does not undergo any photochemical action, and the active layer precursor thin film thereon, and thereafter are sintered and cured into the light-shielding layer pattern 2 and the active layer pattern 3.

As can be appreciated that molecules in the active layer precursor thin film are bonded together using a Van der Waals force, and the photosensitive component in the light-shielding thin film in the exposure area undergoes a photochemical action, thus resulting in nitrogen gas, i.e., gas bubbles, which may push and break the part of the active layer precursor thin film corresponding to the exposure area. In the development process, the exposed area of the light-shielding thin film is dissolved in the development solution, and also the broken part of the active layer precursor thin film is stripped away, but the other part thereof which is not exposed will not be affected, thus forming the light-shielding layer pattern 2 and the active layer pattern 3.

It shall be noted that the thickness of the active layer precursor thin film ranges from 100 Å to 700 Å, and is substantially transparent, so it will not affect the exposure process of the light-shielding thin film.

Accordingly, in the method for fabricating a thin film transistor according to some embodiments of the disclosure, the exposure and development processes are performed using the photosensitive imaging characteristic of the photosensitive resin to pattern it so that the light-shielding layer pattern 2 and the active layer pattern 3 can be formed, thus dispensing with a number of process steps, improving a production throughput, and lowering a cost, as compared with the related art in which the desirable active layer pattern 3 is formed separately through exposing and developing, etching, and stripping away photoresist after the light-shielding layer pattern 2 is formed in a patterning process.

Further to the technical solution above, it shall be noted that the photosensitive resin is optionally positive photoresist resin. Optionally, the photosensitive resin is a photosensitive resin which can absorb a wavelength below 550 nm, e.g., black or dark photosensitive resin.

Further to the technical solution above, optionally, the thickness of the light-shielding layer pattern 2 ranges from 500 Å to 20000 Å.

Further to the technical solution above, the active layer precursor thin film is formed on the light-shielding thin film as follows.

Indium acetylacetonate solution is coated on the surface of the light-shielding thin film to form a thin film of indium acetylacetonate.

Active components of hydrated gallium nitrate and zinc oxide are dissolved in organic solvent to form solution, coated on the thin film of indium acetylacetonate, and exposed into a zinc-gallium-indium oxide precursor thin film.

Further to the technical solution above, the gate insulation layer 4, the gate pattern 5, the interlayer insulation layer 6, and the source and drain electrodes 7 are formed on the active layer pattern 3 as follows.

Referring to FIG. 2B, a gate metal layer is formed on the gate insulation layer 4, and etched in a photolithography process to form the gate pattern 5, and the part of the active layer pattern 3, which is not covered with the gate pattern 5 is plasma-etched and conductized into conductor areas, e.g., a conductor area 31, a conductor area 32, and a conductor area 33 as illustrated in FIG. 2B.

Furthermore, it shall be noted that there are a controllable area 34 between the conductor area 31 and the conductor area 32, and a controllable area 35 between the conductor area 32 and the conductor area 33.

Referring to FIG. 2C, the interlayer insulation layer 6 is formed on the gate pattern 5, and a through-hole is formed on the interlayer insulation layer 6.

Referring to FIG. 2D, a metal layer for source and drain electrodes 7 is formed on the interlayer insulation layer 6, and patterned into a pattern of source and drain electrodes 7 electrically connected with the active layer pattern 3 through the through-hole.

It shall be noted that in order that there is no difference in exposure variation between the gate pattern 5 and the gate insulation layer 4 to thereby eliminate uncontrolled areas, the gate insulation layer 4 is not etched for a while after the gate metal layer is etched. The uncontrolled areas are non-conductor areas which are not controlled by the gate pattern 5, and the uncontrolled areas are located on the part of the gate pattern 5, which lies out of an orthographic projection of the active layer pattern 3.

After the gate metal layer is etched in the photolithography process, the photoresist above the formed gate pattern 5 is ashed so that there is no variation of a feature size of the photoresist from a feature size of the gate pattern 5 to thereby eliminate a difference in exposure variation between the gate pattern 5 and the gate insulation layer 4; and thereafter the part of the active layer pattern 3, which is not covered with the gate pattern 5 is further plasma-etched and conductized into conductor areas to thereby eliminate uncontrolled areas, that is, the uncontrolled areas are conductized into the conductor areas, thus further improving the stability of the array substrate fabricated using the method for fabricating a thin film transistor according to the embodiment of the disclosure.

Optionally, as illustrated in FIG. 2D, the conductor area 31 connects the source (or the drain) with the controllable area 34, the conductor area 32 connects the controllable area 34 with the controllable area 35, and the conductor area 33 connects the controllable area 35 with the drain (or the source). When the gate pattern 5 is at a low level, the controllable area 34 and the controllable area 35 located in the area of an orthographic projection of the gate pattern 5 onto the active layer are in insulation status, the source and the drain are not electrically connected with each other. When the gate pattern 5 is at a high level, as illustrated in FIG. 2D, the controllable area 34 and the controllable area 35 located in the area of an orthographic projection of the gate pattern 5 onto the active layer are changed from a non-conductor state to a conductor state, and at this time, the conductor area 31, the controllable area 34, the conductor area 32, the controllable area 35, and the conductor area 33 communicate with each other, so that the source and the drain are electrically connected with each other.

An embodiment of the disclosure further provides a thin film transistor including follows.

A light-shielding layer pattern 2, and an active layer pattern 3 are arranged on an underlying substrate 1, where the active layer pattern 3 is located on the side of the light-shielding layer pattern 2 away from the underlying substrate 1, and the material of the light-shielding layer pattern 2 is resin.

It shall be noted that in the thin film transistor above, the material of the light-shielding layer pattern 2 is resin, and since the resin material is not a conductor, no buffer layer will be arranged between the light-shielding layer pattern 2 and the active layer pattern 3 to space them from each other. This structure can save a cost of fabricating the entire array substrate, but also a capacitance, and the number of inductive charges between the light-shielding layer, and the source and drain electrodes 7 can be lowered, thus improving the stability and bias trustworthiness of the Thin Film Transistor (TFT), and eliminating the dual-TFT effect.

Further to the technical solution above, the thin film transistor above further includes a gate insulation layer 4, a gate pattern 5, an interlayer insulation layer 6, and source and drain electrodes 7, arranged on the side of the active layer pattern 3 away from the underlying substrate 1.

The material of the active layer 3 is zinc-gallium-indium oxide or zinc-tin-indium oxide; and/or

the material of the interlayer insulation layer 6 is tin nitride, and the thickness of the interlayer insulation layer 6 ranges from 300 nm to 400 nm; and/or

the material of the source and drain electrodes 7 is metal molybdenum, metal aluminum, or metal copper, and the thickness of the source and drain electrodes 7 ranges from 200 nm to 300 nm.

It shall be noted that the materials of the interlayer insulation layer 6, and the source and drain electrodes 7 will not be limited thereto.

Further to the technical solution above, it shall be noted that there may be a number of structures, including at least one of the following several structures, of the thin film transistor according to the embodiment of the disclosure dependent upon the positions where the gate insulation layer 4, the gate pattern 5, the interlayer insulation layer 6, and the source and drain electrodes 7 are arranged in the thin film transistor.

In a first structure, referring to FIG. 2D, a thin film transistor according to an embodiment of the disclosure includes

a light-shielding layer pattern 2 and an active layer pattern 3 arranged on the underlying substrate 1, where the active layer pattern 3 is located on the side of the light-shielding layer pattern 2 away from the underlying substrate 1, and the material of the light-shielding layer pattern 2 is resin; and

the thin film transistor further includes: a gate insulation layer 4 formed on the side of the active layer pattern 3 away from the underlying substrate 1;

a gate pattern 5 formed on the side of the gate insulation layer 4 away from the underlying substrate 1;

an interlayer insulation layer 6 formed on the side of the gate pattern 5 away from the underlying substrate 1; and

source and drain electrodes 7 formed on the interlayer insulation layer 6 away from the underlying substrate 1, where the source and drain electrodes 7 are connected with the active layer pattern 3 through a through-hole.

In a second structure, referring to FIG. 3, a thin film transistor according to an embodiment of the disclosure includes:

a light-shielding layer pattern 2 and an active layer pattern 3 arranged on the underlying substrate 1, where the active layer pattern 3 is located on the side of the light-shielding layer pattern 2 away from the underlying substrate 1, and the material of the light-shielding layer pattern 2 is resin; and

the thin film transistor further includes: source and drain electrodes 7 lapped on the side of the active layer pattern 3 away from the underlying substrate 1;

a gate insulation layer 4 formed on the sides of the source and drain electrodes 7 away from the underlying substrate 1;

a gate pattern 5 formed on the side of the gate insulation layer 4 away from the underlying substrate 1; and

an interlayer insulation layer 6 formed on the side of the gate pattern 5 away from the underlying substrate 1.

In a third structure, referring to FIG. 4, a thin film transistor according to an embodiment of the disclosure includes:

a light-shielding layer pattern 2 and an active layer pattern 3 arranged on the underlying substrate 1, where the active layer pattern 3 is located on the side of the light-shielding layer pattern 2 away from the underlying substrate 1, and the material of the light-shielding layer pattern 2 is resin; and

the thin film transistor further includes: source and drain electrodes 7 arranged between the active layer pattern 3 and the light-shielding layer pattern 2;

a gate insulation layer 4 formed on the side of the active layer pattern 3 away from the underlying substrate 1;

a gate pattern 5 formed on the side of the gate insulation layer 4 away from the underlying substrate 1; and

an interlayer insulation layer 6 formed on the side of the gate pattern 5 away from the underlying substrate 1.

It shall be noted that in the technical solutions in the first, second, and third structures, the part of the active layer pattern 3, which lies out of the area of a orthographic projection of the gate pattern 5 onto the active layer pattern 3 is conductized into conductor areas.

An embodiment of the disclosure further provides an array substrate including the thin film transistors according to any one of the technical solutions above.

An embodiment of the disclosure further provides a display device including the array substrate according to any one of the technical solutions above.

Evidently those skilled in the art can make various modifications and variations to the disclosure without departing from the spirit and scope of the disclosure. Thus the disclosure is also intended to encompass these modifications and variations thereto so long as the modifications and variations come into the scope of the claims appended to the disclosure and their equivalents.

1. A method for fabricating a thin film transistor, the method comprising:
forming a light-shielding layer pattern and an active layer pattern on an underlying substrate in a patterning process, wherein the active layer pattern is arranged on a side of the light-shielding layer pattern away from the underlying substrate, and a material of the light-shielding layer pattern is resin; and
forming a gate insulation layer, a gate pattern, an interlayer insulation layer, and source and drain electrodes on the active layer pattern.

2. The method according to claim 1, wherein the light-shielding layer pattern and the active layer pattern are formed on the underlying substrate in one patterning process.

3. The method according to claim 2, wherein the material of the light-shielding layer pattern is photosensitive resin, and the patterning process for forming the light-shielding layer pattern and the active layer pattern formed on the underlying substrate comprises:
coating photosensitive resin material on the underlying substrate, and forming a light-shielding thin film in a soft-baking process;
forming an active layer precursor thin film on the light-shielding thin film; and
exposing and developing, and sintering and curing the light-shielding thin film and the active layer precursor thin film into the light-shielding layer pattern and the active layer pattern.

4. The method according to claim 3, wherein the forming the active layer precursor thin film on the light-shielding thin film comprises:
coating indium acetylacetonate solution on the surface of the light-shielding thin film to form a thin film of indium acetylacetonate; and
dissolving active components of hydrated gallium nitrate and zinc oxide in organic solvent to form solution, coating the solution on the thin film of indium acetylacetonate, and exposing the thin film into a zinc-gallium-indium oxide precursor thin film.

5. The method according to claim 1, wherein the forming the gate insulation layer, the gate pattern, the interlayer insulation layer, and the source and drain electrodes on the active layer pattern comprises:
forming a gate metal layer on the gate insulation layer, etching the gate metal layer in a photolithography process to form the gate pattern, and conductizing a part of the active layer pattern, which is not covered with the gate pattern, into conductor areas by plasma-etching;
forming the interlayer insulation layer on the gate pattern, and forming a through-hole on the interlayer insulation layer; and
forming a metal layer for source and drain electrodes on the interlayer insulation layer, and patterning the metal layer for source and drain electrodes into a source and drain electrodes pattern electrically connected with the active layer pattern through the through-hole.

6. A thin film transistor, comprising:
a light-shielding layer pattern, and an active layer pattern, which are arranged on an underlying substrate, wherein the active layer pattern is arranged on a side of the light-shielding layer pattern away from the underlying substrate, and a material of the light-shielding layer pattern is resin.

7. The thin film transistor according to claim 6, wherein the thin film transistor further comprises a gate insulation layer, a gate pattern, an interlayer insulation layer, and source and drain electrodes, arranged on the side of the active layer pattern away from the underlying substrate, wherein the thin film transistor further comprises at least one of following features:
the material of the active layer is zinc-gallium-indium oxide or zinc-tin-indium oxide,
the material of the interlayer insulation layer is tin nitride, and the thickness of the interlayer insulation layer ranges from 300 nm to 400 nm or
the material of the source and drain electrodes is metal molybdenum, metal aluminum, or metal copper, and the thickness of the source and drain electrodes ranges from 200 nm to 300 nm.

8. The thin film transistor according to claim 7, wherein the gate insulation layer is formed on a side of the active layer pattern away from the underlying substrate;
the gate pattern is formed on a side of the gate insulation layer away from the underlying substrate;
the interlayer insulation layer is formed on the a side of the gate pattern away from the underlying substrate; and
the source and drain electrodes are formed on a side of the interlayer insulation layer away from the underlying substrate, where the source and drain electrodes are connected with the active layer pattern through a through-hole.

9. The thin film transistor according to claim 7, wherein the source and drain electrodes are lapped on a side of the active layer pattern away from the underlying substrate;
the gate insulation layer is formed on a sides of the source and drain electrodes away from the underlying substrate;
the gate pattern is formed on a side of the gate insulation layer away from the underlying substrate; and
the interlayer insulation layer is formed on a side of the gate pattern away from the underlying substrate.

10. The thin film transistor according to claim 7, wherein the source and drain electrodes are arranged between the active layer pattern and the light-shielding layer pattern;
the gate insulation layer is formed on a side of the active layer pattern away from the underlying substrate;
the gate pattern is formed on a side of the gate insulation layer away from the underlying substrate; and
the interlayer insulation layer is formed on a side of the gate pattern away from the underlying substrate.

11. An array substrate, comprising the thin film transistors according to claim 6.

12. A display device, comprising the array substrate according to claim 11.
